(19) United States
(12) Patent Application Publication
(10) Pub. No.: US 2023/0230853 A1
(43) Pub. Date: Jul. 20, 2023

(54) MANUFACTURING APPARATUS AND MANUFACTURING METHOD OF SEMICONDUCTOR DEVICE

(71) Applicant: SHINKAWA LTD., Tokyo (JP)

(72) Inventors: Daisuke TANI, Tokyo (JP); Takahiro SHIMIZU, Tokyo (JP); Masafumi MIYAMOTO, Tokyo (JP)

(73) Assignee: SHINKAWA LTD., Tokyo (JP)

(21) Appl. No.: 18/009,984

(22) PCT Filed: Jun. 14, 2021
(86) PCT No.: PCT/JP2021/022561

§ 371 Date: Dec. 13, 2022

(30) Foreign Application Priority Data
Jun. 15, 2020 (JP) 2020-103333

(51) Int. Cl. H01L 21/50; H01L 23/00

(52) U.S. Cl. CPC H01L 21/50; H01L 24/75; H01L 2224/7592; H01L 2224/75301; H01L 2224/7555

(57) ABSTRACT

A manufacturing apparatus of a semiconductor device includes a stage, a mounting tool, a pressing mechanism, and a controller. The pressing mechanism moves the mounting tool in a vertical direction and applies a load to a chip. The controller is configured to perform a first process and a detection process. In the first process, after bringing the chip into contact and until a bump melts, the chip is heated by the mounting tool and a command position of the pressing mechanism is constantly updated so that a positional deviation is constant. In the detection process, melting of the bump is detected based on a decrease in the pressing load.

### TECHNICAL FIELD

This specification discloses a manufacturing apparatus and a manufacturing method for manufacturing a semiconductor device by bonding a chip held by a mounting tool to a substrate.

### RELATED ART

A flip chip bonder is conventionally known as a technique for mounting a chip on a substrate. In the flip chip bonder, protruding electrodes called bumps are formed on the bottom surface of the chip. A mounting tool is used to press the chip against the substrate and heat the chip to melt the bumps to bond the bumps of the chip to the electrodes of the substrate. In recent years, several techniques have been proposed for detecting a melting timing of the bumps in such bonding processes.

For example, Patent Document 1 discloses a technique in which if a load detection value detected by a load detection means provided in a thermocompression bonding tool (corresponding to the mounting tool) decreases to a predetermined value or below, it is determined that the bumps have melted and the thermocompression bonding tool is raised. According to this technique, if melting of the bumps can be detected, the next operation, that is, raising the thermocompression bonding tool, can be performed immediately. As a result, the time required for thermocompression bonding can be shortened and productivity can be improved compared to a technique of presuming a time taken until melting occurs and continuing heating until the presumed time elapses.

### RELATED ART DOCUMENTS

### Patent Document

Patent Document 1: Japanese Patent Application Laid-Open No. 1111-145197

### SUMMARY OF INVENTION

### Problem to Be Solved by Invention

In the technique of Patent Document 1, when heating and pressing the chip, the position of the mounting tool is held constant. However, the mounting tool extends axially due to thermal expansion until the bumps melt. If the position of the mounting tool is held constant, the load applied to the chip gradually increases due to the extension of the mounting tool. Then, there is a risk that the bumps would be crushed more than necessary. If the bumps are crushed, the gap, which is the distance between the chip and the substrate, cannot be kept at an appropriate value. Further, if the bumps are crushed and spread in the surface direction, there is a risk of a short circuit with adjacent bumps.

In other words, the conventional technique cannot properly maintain the quality of the bumps. Therefore, this specification discloses a manufacturing apparatus and a manufacturing method of a semiconductor device capable of appropriately maintaining the quality of bumps while detecting a melting timing of the bumps.

### Means for Solving Problem

A manufacturing apparatus of a semiconductor device disclosed in this specification includes a stage, a mounting tool, a pressing mechanism, and a controller. The stage supports a substrate. The mounting tool heatably holds a chip having a bump on a bottom surface. The pressing mechanism moves the mounting tool in a vertical direction and applies a load to the chip. The controller controls drive of the mounting tool and the pressing mechanism. The controller is configured to perform a first process and a detection process. In the first process, after bringing the chip into contact with the substrate and until the bump melts, the chip is heated by the mounting tool and a command position of the pressing mechanism in the vertical direction is constantly updated so that a positional deviation, which is a difference between the command position and a current position of the pressing mechanism, is constant. In the detection process, in parallel with the first process, a pressing load of the chip applied by the pressing mechanism is monitored and melting of the bump is detected based on a decrease in the pressing load.

In this case, the controller may further perform a second process of constantly updating the command position of the pressing mechanism after a time point at which melting of the bump is detected in the detection process, so that a gap amount, which is a distance between the bottom surface of the chip and the substrate, is kept at a target value.

In this case, the pressing mechanism may include a drive motor which moves the mounting tool in the vertical direction. In the detection process, the controller may monitor an electric current value of the drive motor as a parameter indicating the pressing load.

Further, in the first process, the controller may calculate, as the command position of the pressing mechanism, a value obtained by subtracting a target value of the positional deviation from a current position of the mounting tool.

A manufacturing method of a semiconductor device disclosed in this specification includes a first step and a detection step. In the first step, after bringing a chip held by a mounting tool into contact with a substrate supported by a stage and until a bump provided on a bottom surface of the chip melts, the chip is heated by the mounting tool and a command position in a vertical direction of a pressing mechanism, which moves the mounting tool in the vertical direction, is constantly updated so that a positional deviation, which is a difference between the command position and a current position of the pressing mechanism, is constant. In the detection step, in parallel with the first step, a pressing load of the chip applied by the pressing mechanism is monitored and melting of the bump is detected based on a decrease in the pressing load.

In this case, a second step may be further included. In the second step, the command position of the pressing mechanism is constantly updated after a time point at which melting of the bump is detected in the detection step, so that a gap amount, which is a distance between the bottom surface of the chip and the substrate, is kept at a target value.

### Effect of Invention

According to the technique disclosed in this specification, it is possible to appropriately maintain the quality of bumps while detecting a melting timing of the bumps.

### BRIEF DESCRIPTION OF DRAWINGS

FIG. 1 is an image view showing a configuration of a manufacturing apparatus of a semiconductor device.

FIG. 2 is an image view showing mounting of a semiconductor chip.

FIG. 3 is a graph showing over-time changes in various parameters during mounting of the semiconductor chip.

FIG. 4 is a flowchart showing a flow of a manufacturing method of a semiconductor device.

FIG. 5 is a flowchart showing a flow of the manufacturing method of a semiconductor device.

### DESCRIPTION OF EMBODIMENTS

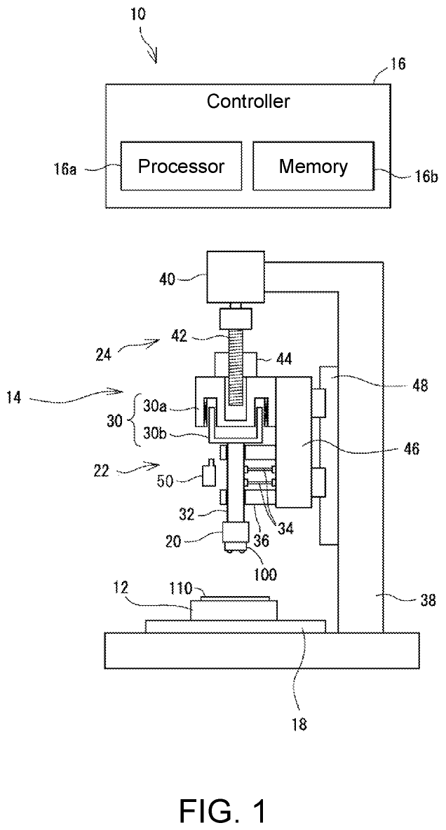

Hereinafter, a manufacturing apparatus 10 of a semiconductor device will be described with reference to the drawings. FIG. 1 is an image view showing a configuration of the manufacturing apparatus 10 of a semiconductor device. The manufacturing apparatus 10 is an apparatus that manufactures a semiconductor device by mounting a semiconductor chip 100, which is an electronic component, onto a substrate 110 in a face-down state. The manufacturing apparatus 10 includes a bonding head 14 which has a mounting tool 20, a chip supply means (not shown) which supplies the semiconductor chip 100 to the mounting tool 20, a stage 12 which supports the substrate 110, an XY stage 18 which moves the stage 12 in the XY direction (horizontal direction), and a controller 16 which controls drive of these components.

The substrate 110 is held by suction on the stage 12 and is heated by a stage heater (not shown) provided on the stage 12. Further, the semiconductor chip 100 is supplied to the mounting tool 20 by the chip supply means. Various configurations of the chip supply means are conceivable. For example, in a conceivable configuration, a semiconductor chip is picked up by a relay arm from a wafer placed on a wafer stage and transferred to a relay stage. In this case, the XY stage 18 transfers the relay stage to directly below the mounting tool 20, and the mounting tool 20 picks up the semiconductor chip from the relay stage located directly below.

After the semiconductor chip is picked up by the mounting tool 20, the substrate 110 is then transferred by the XY stage 18 to directly below the mounting tool 20. In this state, the mounting tool 20 lowers toward the substrate 110, and presses and mounts the semiconductor chip 100, which is held by suction at its end, to the substrate 110.

The mounting tool 20 holds the semiconductor chip 100 by suction and heats the semiconductor chip 100. For this purpose, the mounting tool 20 is provided with a suction hole communicated with a vacuum source, and a tool heater for heating the semiconductor chip 100 (both not shown). In addition to the mounting tool 20 described above, the bonding head 14 is further provided with a pressing mechanism 22 and an elevating mechanism 24.

By moving the mounting tool 20 in the Z-axis direction (i.e., the vertical direction), the pressing mechanism 22 presses the semiconductor chip 100 against the substrate 110 and applies a pressing load to the semiconductor chip 100. The pressing mechanism 22 includes a drive motor 30, a slide shaft 32, a leaf spring 34, and a guide member 36. The drive motor 30 is a drive source for the pressing mechanism 22, and is, for example, a voice coil motor. The drive motor 30 includes a stator 30a fixed to a moving body 46 and a mover 30b movable in the Z-axis direction with respect to the stator 30a. The mover 30b is mechanically connected to the mounting tool 20 via the slide shaft 32. Further, the slide shaft 32 is attached to the moving body 46 via the leaf spring 34 which is bendable in the Z-axis direction. Further, the guide member 36 is fixed to the moving body 46. The slide shaft 32 is inserted through a through hole formed in the guide member 36 and is slidable along the through hole.

When an electric current is applied to the drive motor 30, the mover 30b moves in the Z-axis direction with respect to the moving body 46. At this time, the slide shaft 32 and the mounting tool 20 fixed to the slide shaft 32 move in the Z-axis direction together with the mover 30b while elastically deforming the leaf spring 34. A displacement amount of the slide shaft 32 with respect to the stator 30a is detected by a position sensor such as a linear scale 50 fixed to the guide member 36 and is sent to the controller 16.

The elevating mechanism 24 raises and lowers the mounting tool 20 and the pressing mechanism 22 in the Z-axis direction with respect to a base member 38. The elevating mechanism 24 includes an elevating motor 40 as a drive source. A lead screw 42 extending in the axial direction is connected to the elevating motor 40 via a coupling, and the lead screw 42 rotates along with the drive of the elevating motor 40. A moving block 44 is screwed to the lead screw 42, and the moving block 44 is fixed to an upper surface of the stator 30a of the drive motor 30. Further, the moving body 46 is fixed to a side surface of the stator 30a. The moving body 46 is slidable along a guide rail 48 fixed to the base. When an electric current is applied to the elevating motor 40, the lead screw 42 rotates, and along with this, the moving block 44 rises and lowers in the Z-axis direction. Then, with the moving block 44 rising and lowering, the pressing mechanism 22 and the mounting tool 20 fixed to the moving block 44 also rise and lower. A rising and lowering amount of the pressing mechanism 22 by the elevating mechanism 24 is also detected by a sensor (e.g., an encoder attached to the elevating motor 40) and sent to the controller 16.

The controller 16 controls drive of the mounting tool 20, the pressing mechanism 22, the elevating mechanism 24, the stage 12, and the XY stage 18. The controller 16 is physically a computer including a processor 16a and a memory 16b. This “computer” also includes a microcontroller that incorporates a computer system into one integrated circuit. Further, the processor 16a refers to a processor in a broad sense and includes a general-purpose processor (e.g., a central processing unit (CPU)) or a dedicated processor (e.g., a graphics processing unit (GPU), an application specific integrated circuit (ASIC), a field programmable gate array (FPGA), and a programmable logic device). Further, the operation of the processor 16a described below may be achieved not only by one processor, but also by cooperation of a plurality of processors present at physically separated positions. Similarly, the memory 16b does not have to be physically one element, but may be composed of a plurality of memories present at physically separated positions. Further, the memory 16b may include at least one of a semiconductor memory (e.g., a RAM, a ROM, and a solid state drive) and a magnetic disk (e.g., a hard disk drive).

Herein, drive control of the drive motor 30 by the controller 16 will be briefly described. When driving the drive motor 30, the controller 16 first acquires a detection value of the linear scale 50 as a detection position Pd of the mounting tool 20 in the Z-axis direction, and acquires a differential value of the detection value of the linear scale 50 as a speed detection value. Then, the controller 16 calculates a speed command value based on a positional deviation, which is a deviation between the detection position of the mounting tool 20 in the Z-axis direction and a command position, calculates a torque command value based on a deviation between the speed command value and the speed detection value, and applies an electric current corresponding to the torque command value to the drive motor 30. Herein, in this example, the drive motor 30 is a voice coil motor and outputs a torque proportional to the applied electric current. Accordingly, the electric current value applied to the drive motor 30 is substantially proportional to the pressing load applied to semiconductor chip 100. Thus, in this example, the controller 16 acquires the electric current value of the drive motor 30 as a parameter indicating the pressing load. Further, the controller 16 sequentially updates the command position used in the control of the drive motor 30 according to the flow of the mounting process, which will be described later.

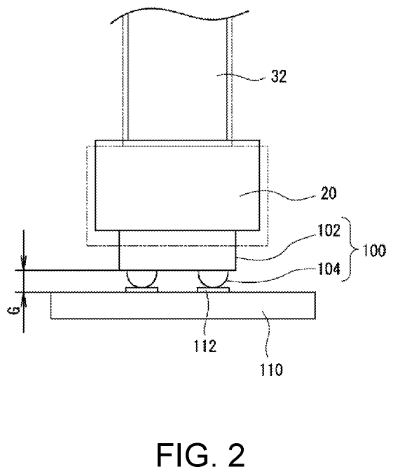

Next, a mounting method of the semiconductor chip 100 by the above-described manufacturing apparatus 10 will be described. FIG. 2 is an image view showing mounting of the semiconductor chip 100. As shown in FIG. 2, a plurality of electrodes 112 are formed on an upper surface of the substrate 110. Further, the semiconductor chip 100 has a plurality of bumps 104 which protrude from a bottom surface of a chip body 102 and are formed of conductive metal such as solder. When mounting the semiconductor chip 100, with the bumps 104 being brought into contact with the electrodes 112 of the substrate 110, the semiconductor chip 100 is heated to melt the bumps 104. Then, by melting the bumps 104, the bumps 104 and the electrodes 112 are joined. Although not shown in FIG. 2, the bottom surface of the chip body 102 may be further provided with a thermosetting resin layer such as a non-conductive film layer.

Herein, during this mounting, if pressing of the semiconductor chip 100 continues even after the bumps 104 have melted, the melted bumps may be deformed and crushed. In this case, a bump 104 that has crushed and spread laterally may cause a short circuit with an adjacent bump 104.

Thus, conventionally, a technique has been proposed to continuously apply a load to the semiconductor chip 100 by the mounting tool 20, detect a timing at which sinking of a certain level or more has occurred in the mounting tool 20 as a melting timing of the bumps 104, and thereafter, reduce the load applied to the semiconductor chip 100. However, in the case of such a technique of detecting sinking of the mounting tool 20, it is not possible to accurately determine whether the sinking results from melting of the bumps 104 or from breakage of the bumps 104 before melting. Further, in this conventional technique, the mounting tool 20 temporarily sinks greatly, so there is a risk that the melted bumps 104 may crush and spread laterally.

Thus, in Patent Document 1, in place of a sinking amount of the mounting tool 20, it is determined that the bumps 104 have melted when a load detection value obtained by a load detection means provided in the mounting tool 20 decreases to a predetermined position or below. According to this technique, sinking of the mounting tool 20 can be suppressed to some extent. However, in Patent Document 1, from the start of heating until the bumps 104 are melted, the mounting tool 20 is not raised or lowered in order to keep the Z-axis direction position of the mounting tool 20 constant, and thermal expansion of the mounting tool 20 due to heating is not considered.

That is, when mounting the semiconductor chip 100, the built-in tool heater of the mounting tool 20 is heated to heat the semiconductor chip 100. With this heating, the mounting tool 20 thermally expands in its longitudinal direction, as indicated by a double-dot dashed line in FIG. 2. Thus, even if the mounting tool 20 is stationary without being raised or lowered, an end surface of the mounting tool 20 is displaced downward due to thermal expansion, and the pressing load increases. As a result, in Patent Document 1, as thermal expansion progresses, the pressing load increases, and there is a risk that the bumps 104 before melting may be broken or the melted bumps 104 may be excessively crushed. Further, in the technique of Patent Document 1, since the influence of thermal expansion is not considered, there is a risk that a gap amount G, which is a distance between the bottom surface of the chip body 102 and the upper surface of the substrate 110, cannot be set to a desired value.

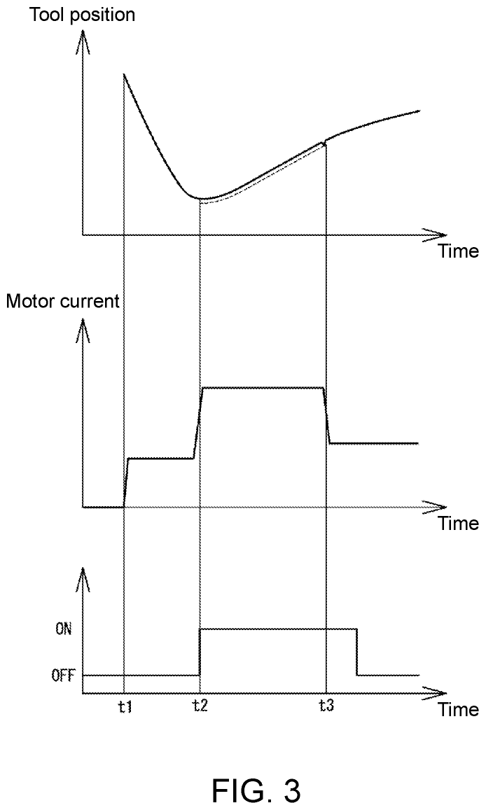

In this specification, to properly detect melting of the bumps 104, the pressing load applied to the semiconductor chip 100 is monitored, and a timing at which the pressing load suddenly decreases is detected as a melting timing of the bumps 104. Further, to prevent breakage of the bumps 104 before melting, until the bumps 104 melt, the command position is sequentially updated so that even if the mounting tool 20 thermally expands, a positional deviation, which is a deviation between a current position of the mounting tool 20 and the command position, is constant. The flow of mounting of the semiconductor chip 100 will be described below with reference to FIG. 3 to FIG. 5.

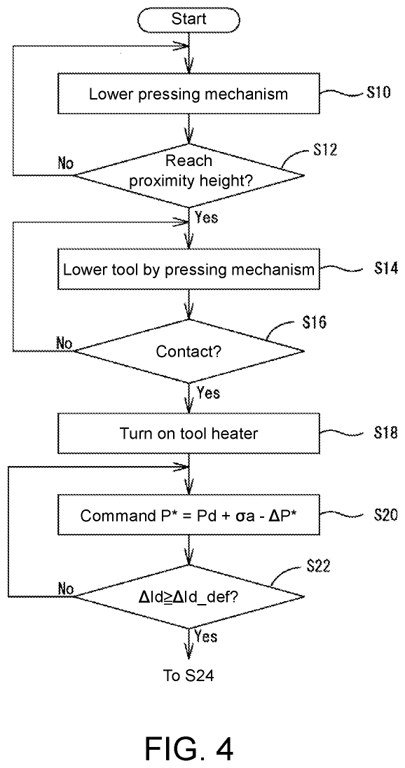

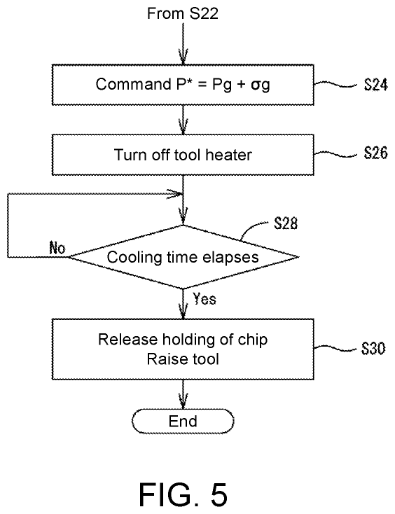

FIG. 3 is a graph showing over-time changes in various parameters during mounting of the semiconductor chip 100, with the upper part showing the detection value of the linear scale 50, the middle part showing the electric current value of the driving motor 30, and the lower part showing the drive state of the tool heater. FIG. 4 and FIG. 5 are flowcharts showing the flow of a manufacturing method of a semiconductor device.

When mounting the semiconductor chip 100 on the substrate 110, the stage 12 is horizontally aligned with the mounting tool 20 so that the bumps 104 of the semiconductor chip 100 are positioned directly above the electrodes 112 of the substrate 110. The flowchart of FIG. 4 starts from this state. Afterwards, the controller 16 drives the elevating motor 40 to lower the mounting tool 20 together with the pressing mechanism 22 at a high speed (S10). When the semiconductor chip 100 approaches the substrate 110 until a slight gap remains between the semiconductor chip 100 and the substrate 110 (Yes in S12), the controller 16 stops drive of the elevating motor 40. Time t1 in FIG. 3 indicates a timing at which the semiconductor chip 100 has approached the substrate 110.

After the semiconductor chip 100 has approached the substrate 110, the controller 16 drives the drive motor 30 to lower the mounting tool 20 at a low speed until the bumps 104 come into contact with the electrodes 112 (S14). Specifically, until contact is detected, the controller 16 gradually updates the command position P* inputted to the drive motor 30 so that the mounting tool 20 gradually approaches the substrate 110. A contact timing of the bumps 104 may be determined based on the detection position, or may be determined based on the electric current value of the drive motor 30. That is, when the bumps 104 come into contact with the electrodes 112, the detection position Pd does not change even if the command position P* is updated. Thus, the timing indicated by the change in the detection position Pd may be determined as the contact timing. Further, when the bumps 104 come into contact with the electrodes 112, the semiconductor chip 100 and the mounting tool 20 receive a reaction force from the substrate 110. As the drive motor 30 attempts to output a torque corresponding to this reaction force, the electric current value of the drive motor 30 suddenly increases. The sudden increase timing of the electric current value may be determined as the contact timing. In FIG. 3, contact is detected at time t2.

If contact of the bumps 104 is detected (Yes in S16), a first process (S18, S20) is executed to start heating the semiconductor chip 100 by the tool heater and constantly update the command position P* of the drive motor 30 so that the positional deviation ΔP is constant. That is, at time t2 when contact is detected, the controller 16 turns on the tool heater mounted on the mounting tool 20 to start heating the semiconductor chip 100 (S18). Further, the controller 16 constantly updates the command position P* of the drive motor 30 according to a formula P*=Pd+σa−ΔP*. Herein, Pd is the detection position of the mounting tool 20. σa is the thermal expansion amount of the mounting tool 20 that occurs per sampling. The thermal expansion amount as per sampling is acquired in advance by experiments or the like. Further, the thermal expansion amount σa per sampling may be a fixed value, or may be a variable value that changes with the lapse of time or temperature change of the tool heater. Pd+σa is the current position of the mounting tool 20. ΔP* is a target value of the positional deviation ΔP, and is a constant fixed value. A dashed line in FIG. 3 indicates the command position P* used during the first process.

Thus, by constantly updating the command position P* based on the formula P*=Pd+σa−ΔP*, even if the mounting tool 20 or the semiconductor chip 100 thermally expands, the positional deviation ΔP can always be kept constant. By keeping the positional deviation ΔP constant, the output torque from the drive motor 30 and thus the pressing load of the semiconductor chip 100 can be kept substantially constant. Accordingly, it is possible to effectively prevent the bumps 104 before melting from being broken and crushed.

In parallel with the first process, the controller 16 also monitors the pressing load applied to the semiconductor chip 100 (S22). Since the pressing load is substantially proportional to the electric current value Id of the drive motor 30, the controller 16 monitors the electric current value Id of the drive motor 30 as a parameter indicating the pressing load. As a result of continued heating, when the bumps 104 melt, the reaction force that the mounting tool 20 receives from the semiconductor chip 100 suddenly decreases, and the pressing load and thus the electric current value Id suddenly decrease. The controller 16 determines that melting of the bumps 104 has occurred when the electric current value Id suddenly decreases.

Specifically, the controller 16 calculates a difference ΔId=Id[i−N]−Id[i] between an electric current value Id[i−N] of N samplings ago and an electric current value Id[i] of the present time. Then, the controller 16 compares this difference ΔId with a specified reference value ΔId_def, and determines that the bumps 104 have melted if ΔId≥ΔId_def. N is an integer of 1 or more. In FIG. 3, it is determined that melting occurs at time t3.

In this example, since the command position P* of the mounting tool 20 is set below the current position (Pd+σa), when melting of the bumps 104 occurs and the reaction force from the semiconductor chip 100 decreases, the mounting tool 20 may be displaced downward from the current position (Pd+σa) by the target value ΔP* of the positional deviation to reach the command position P*. A sufficiently small value is set as the target value ΔP* of the positional deviation so that the bumps 104 are not greatly crushed in the displacement during melting of the bumps 104.

If it is determined that the bumps 104 have melted (Yes in S22), the controller 16 executes a second process of controlling the position of the mounting tool 20 so that the gap amount G becomes a desired value (S24). That is, the controller 16 constantly updates the command position P* of the drive motor 30 as P*=Pg+σg. Herein, Pg is the position of the mounting tool 20 when the mounting tool 20 is brought into contact with the semiconductor chip 100 which is in a room temperature state and has a gap amount G being the desired value. Hereinafter, this Pg will be referred to as a “standard position.” This standard position Pg is a fixed value calculated in advance based on the value of the gap amount G, the dimension value of the semiconductor chip 100, etc. Further, sag is the thermal expansion amount of the mounting tool 20 and the semiconductor chip 100. This σg is a variable value that changes according to time and heater temperature. By controlling the position of the mounting tool 20 by such a command position P*=Pg+σg, the gap amount G can be kept at a desired value. Further, the controller 16 turns off the tool heater at an appropriate timing (S26). Afterwards, when a cooling time sufficient to harden the bumps 104 has passed (Yes in S28), after releasing suction of the semiconductor chip 100, the controller 16 drives the pressing mechanism 22 and the elevating mechanism 24 to raise the mounting tool 20 (S30).

As is clear from the above description, in this example, the timing at which the electric current value of the drive motor 30 and thus the pressing load suddenly decrease is detected as the melting timing of the bumps 104. With such a configuration, the melting timing of the bumps 104 can be accurately detected without crushing the melted bumps 104. Further, in the first process, the command position P* is constantly updated so that the positional deviation ΔP is constant. Thus, even if thermal expansion occurs, the pressing load can be kept constant. As a result, it is possible to effectively prevent applying an excessive load to the bumps 104 before melting and breaking the bumps 104.

The configuration described so far is only an example, and if a first process is performed to constantly update the command position P* in the vertical direction of the pressing mechanism 22 after contact and until the bumps 104 melt so that the positional deviation ΔP is constant, and a detection process is performed to detect the timing at which the pressing load suddenly decreases as the melting timing of the bumps 104, other configurations may be changed as appropriate. For example, in the description so far, the electric current value of the drive motor 30 is monitored as a parameter indicating the pressing load, but a load sensor may also be provided in the pressing mechanism 22 and a detection value of this load sensor may be monitored. Further, in the above description, the value obtained by adding the thermal expansion amount aa per sampling to the detection position Pd of the mounting tool 20 is treated as the current position of the mounting tool 20, but another value may also be used as the current position if thermal expansion is considered. For example, a profile of displacement of the mounting tool 20 due to thermal expansion may be acquired in advance by experiments or the like, and the current position of the mounting tool 20 may be obtained from this profile. Further, in the above description, the drive motor 30 is used as the drive source of the pressing mechanism 22, but another drive source such as a battery cylinder or a hydraulic cylinder may also be used.

### REFERENCE SIGNS LIST

10 manufacturing apparatus; 12 stage; 14 bonding head; 16 controller; 18 XY stage; 20 mounting tool; 22 pressing mechanism; 24 elevating mechanism; 30 drive motor; 30a stator; 30b mover; 32 slide shaft; 34 leaf spring; 36 guide member; 38 base member; 40 elevating motor; 42 lead screw; 44 moving block; 46 moving body; 48 guide rail; 50 linear scale; 100 semiconductor chip; 102 chip body; 104 bump; 110 substrate; 112 electrode

1. A manufacturing apparatus of a semiconductor device, comprising:
a stage which supports a substrate;
a mounting tool which heatably holds a chip having a bump on a bottom surface;
a pressing mechanism which moves the mounting tool in a vertical direction and applies a load to the chip; and
a controller which controls drive of the mounting tool and the pressing mechanism,
wherein the controller is configured to:
after bringing the chip into contact with the substrate and until the bump melts, perform a first process of heating the chip by the mounting tool and constantly updating a command position of the pressing mechanism in the vertical direction so that a positional deviation, which is a difference between the command position and a current position of the pressing mechanism, is constant; and
in parallel with the first process, perform a detection process of monitoring a pressing load of the chip applied by the pressing mechanism and detecting melting of the bump based on a decrease in the pressing load, and
the controller updates, as the command position, a value obtained by subtracting a target value of the positional deviation greater than 0 from a sum of a detection position of the mounting tool detected by a sensor and a thermal expansion amount per sampling.

2. The manufacturing apparatus of a semiconductor device according to claim 1, wherein
the controller further performs a second process of constantly updating the command position of the pressing mechanism after a time point at which melting of the bump is detected in the detection process, so that a gap amount, which is a distance between the bottom surface of the chip and the substrate, is kept at a target value.

3. The manufacturing apparatus of a semiconductor device according to claim 1, wherein
the pressing mechanism comprises a drive motor which moves the mounting tool in the vertical direction, and
in the detection process, the controller monitors an electric current value of the drive motor as a parameter indicating the pressing load.

4. (canceled)

5. A manufacturing method of a semiconductor device, comprising:
after bringing a chip held by a mounting tool into contact with a substrate supported by a stage and until a bump provided on a bottom surface of the chip melts, performing a first step of heating the chip by the mounting tool and constantly updating a command position in a vertical direction of a pressing mechanism, which moves the mounting tool in the vertical direction, so that a positional deviation, which is a difference between the command position and a current position of the pressing mechanism, is constant; and
in parallel with the first step, performing a detection step of monitoring a pressing load of the chip applied by the pressing mechanism and detecting melting of the bump based on a decrease in the pressing load, wherein
the first step updates, as the command position, a value obtained by subtracting a target value of the positional deviation greater than 0 from a sum of a detection position of the mounting tool detected by a sensor and a thermal expansion amount per sampling.

6. The manufacturing method of a semiconductor device according to claim 5, further comprising:
performing a second step of constantly updating the command position of the pressing mechanism after a time point at which melting of the bump is detected in the detection step, so that a gap amount, which is a distance between the bottom surface of the chip and the substrate, is kept at a target value.
